(19) United States
(12) Patent Application Publication
(10) Pub. No.: US 2007/0022955 A1
(43) Pub. Date: Feb. 1, 2007

(54) Vapor deposition device

(76) Inventors: Marcus Bender, Hanau (DE); Uwe Hoffmann, Alzenau (DE); Gunter Klemm, Nidda (DE); Dieter Haas, Bruchkobel (DE); Ulrich Englert, Heigenbrucken (DE)

Correspondence Address: FULBRIGHT & JAWORSKI, LLP, 666 FIFTH AVE, NEW YORK, NY, 10103-3198, US

(21) Appl. No.: 11/384,016

(22) Filed: Mar. 17, 2006

(30) Foreign Application Priority Data
Jul. 28, 2005 (EP) 050 16 365

(51) Int. Cl. C23C 16/00

(52) U.S. Cl. 118/726

(57) ABSTRACT

A vapor deposition device for the vapor deposition of a substrate, and specifically particular of a substrate comprising heat-sensitive substances, for example OLEDs. To keep heat away from these substances, the vapor deposition device includes an evaporator tube with a special nozzle bar. This nozzle bar, which comprises several linearly arranged openings, projects with respect to the evaporator tube in the direction toward the substrate to be coated.

### BACKGROUND AND SUMMARY OF THE INVENTION

This application claims priority under 35 U.S.C. §119 from European Patent Application No. 050 16 365 filed Jul. 28, 2005, incorporated herein by reference in its entirety.

The invention relates to a vapor deposition device.

Modem flat-screen displays comprise liquid crystal elements (LCEs) or plasma elements for the rendering of images.

Flat-screen displays have also recently been produced which utilize organic light-emitting diodes (OLEDs) as color pixels.

Compared to the already known structural elements, a great advantage of the OLEDs is their high degree of efficiency of more than 16% (Helmuth Lemme: OLEDs—Senkrechtstarter aus Kunststoff, Elektronik 2/2000, p. 98. right column, 2nd paragraph, No. [5]: Yi He; Janicky, J.: High Efficiency Organic Polymer Light-Emitting Heterostructure Devices, Eurodisplay 99, VDE-Verlag Berlin, Offenbach). Therewith the OLEDs are situated far above the quantum efficiency of the LEDs comprised of inorganic III-V semiconductors.

OLEDs, further, have lower weight, a wider angle of radiation, and produce colors of more intense brightness and can be applied in a broad temperature range from −40 C to 85 C. Of advantage is also that they can be operated at less than 5 Volts and have low electric energy consumption, which makes the OLEDs especially suitable for installation in battery-operated apparatus.

The OLEDs can be produced by means of OVPD technology (OVPD=Organic Vapor Phase Deposition), such as is described in U.S. Pat. No. 5,554,220 or DE 101 28 091 C1. Therein the organic materials are applied onto an electrode located on glass. This electrode can be, for example, an ITO electrode (ITO=Indium Tin Oxide) which previously had been vapor deposited onto glass.

Onto the OLED layer generated in this way further materials, in particular metal layers serving as counterelectrodes, can be applied or vapor deposited. Devices for vaporizing metals are known as such (EP 0 477 474 B1, JP 10008241 A1, DE 976 068, U.S. Pat. No. 4,880,960).

In an evaporator device for vaporizing metals which are utilized in the production of OLED flat-screen displays, an evaporator housing is placed perpendicularly onto the crucible (DE 102 56 038 A1). This evaporator device, as does the evaporator device according to DE 101 28 091 A1 also, includes a linear distributor system. In this linear distributor system several evaporator apertures are arranged linearly. The metal vapor escaping through these apertures impinges onto a substrate located parallel to the evaporator apertures.

In the evaporator device according to DE 102 56 038 A1 the thermal insulation is interrupted in the proximity of the outlet apertures for the vapor, as a consequence of which the evaporator tube is colder at this site than at those sites at which the evaporator tube is encompassed by the insulation. This interruption of the thermal insulation leads to the fact that the substrates are subjected to strong thermal loading on the part of the evaporator tube. For, while the evaporator tube becomes relatively cool in the proximity of the outlet apertures, it is still very hot and radiates heat onto the substrate.

To shield the substrate, at least to some extent, against the heat radiated in the proximity of the outlet apertures, retroreflective metal sheeting is provided in the known device.

Lastly, an evaporator device is also known with which the vaporized material can be deposited over a mask onto a plate (JP 2004-214185). This evaporator device comprises an evaporator crucible in which material is vaporized. In the upper region of the crucible is a projecting part directed toward the plate. In the projecting part an opening is provided, and specifically in the direction from the interior of the crucible toward the plate. About the projecting part a shielding is provided located at the same or lower level than the opening and spaced apart from the upper surface of the crucible. It is not possible with this evaporator device to coat flat substrates oriented parallel to the gravitational force of the earth, such as for example glass plates, since the evaporator stream or the evaporator directional lobe is emitted parallel to the direction of the earth's gravitational force.

The aim of the invention is to decrease the thermal loading even of such flat substrates whose surface is oriented parallel to the gravitational force of the earth.

This aim is attained with a device according to the present invention.

The invention consequently relates to a vapor deposition device for the vapor deposition of a substrate, and specifically of a substrate which contains heat-sensitive substances, for example OLEDs. To keep heat away from these substances, the vapor deposition device includes an evaporator tube with a special nozzle bar. This nozzle bar, which includes several linearly arranged openings, relative to the evaporator tube projects in the direction toward the substrate to be coated.

The advantage attained with the invention comprises in particular that the nozzle bar precedes the evaporator tube in such formation that it is possible to insulate the tube up to the nozzle bar leading to a reduction of the heat-radiating area. Due to this improved insulation the substrate is significantly better protected against the radiated heat, such that also heat-sensitive substances, such as for example OLEDs, can be coated with metals.

Embodiment examples of the invention are depicted in the drawing and will be described in further detail in the following.

### BRIEF DESCRIPTION OF THE FIGURES

FIG. 1 is a perspective overall view of a vapor deposition device.

FIG. 2 shows a partially sectioned vapor deposition device.

FIG. 3 shows a longitudinal section through the vapor deposition device according to FIG. 1.

FIG. 4 is an enlarged cut-out from FIG. 2.

FIG. 5 shows a nozzle bar with tapering cone-shaped nozzles forwardly located.

FIG. 6 shows a cut-out of a portion of the evaporator tube with the nozzle bar according to FIG. 5.

### DETAILED DESCRIPTION

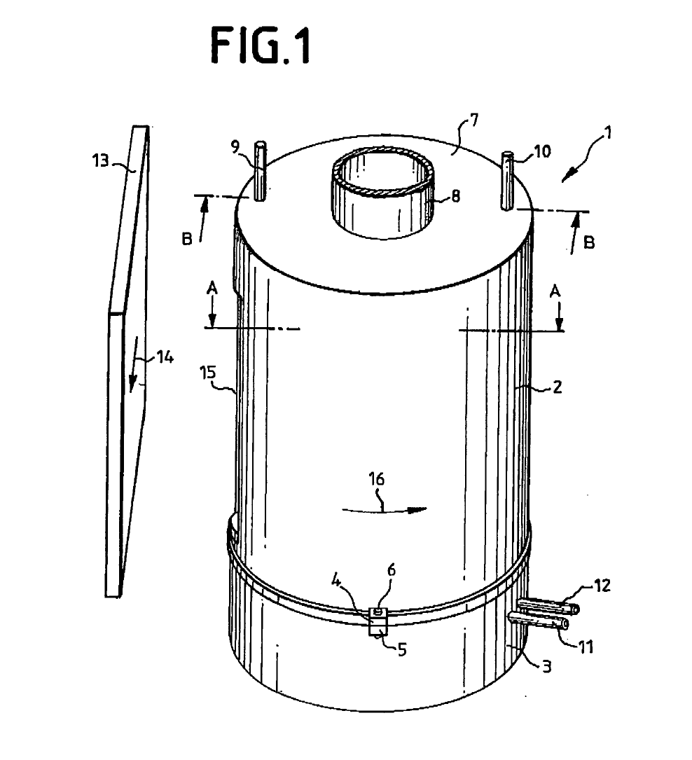

FIG. 1 depicts a perspective overall view of a vapor deposition device 1 comprising an upper part 2 and a lower part 3. Both parts 2, 3 are held together by an upper and a lower connection clamp 4, 5 as well as by a bolt 6. Several such connection clamps and bolts may be provided over the circumference of the vapor deposition device 1.

On the top side 7 of the upper part 2 an inlet tube 8 is indicated. By 9 and 10 are denoted cooling means ports, which are also located on the top side of the upper part 2.

Further cooling means ports 11, 12 are located on the lower part 3.

The vapor deposition device 1 stands perpendicularly, i.e. parallel to the direction of the gravitational force of the earth. A substrate 13 to be coated, for example a glass plate coated with OLED, is guided past the vapor deposition device 1, and specifically horizontally, as indicated by arrow 14. The OLED may be disposed on an ITO layer, which forms a first electrode. The metal layer now to be vapor deposited in this case forms, for example, the second electrode.

In the upper part 2 of the vapor deposition device opposite the substrate 13 is a vertically disposed gap 15 through which coating material reaches the surface of the substrate 13. Consequently, the coating material reaches the surface of substrate 13 linearly and perpendicularly.

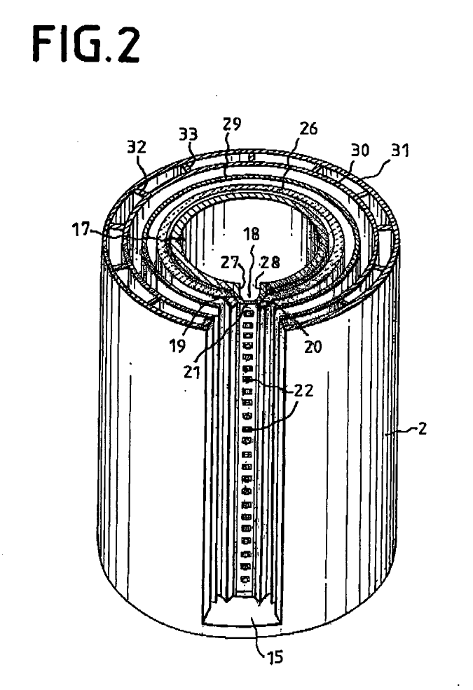

FIG. 2 shows again the upper part 2 of the vapor deposition device 1 in a partially sectioned illustration. Through the section A-A parallel to the footprint, the internal structure of the upper part 2 can be seen.

Compared to the illustration of FIG. 1, the upper part 2 is rotated about 90 degrees, such that details of the gap 15 can be seen. The rotation takes place in the direction of arrow 16 (FIG. 1) i.e. in the counterclockwise direction.

In this upper part 2 an interior evaporator tube 17 at a site of its circumference is provided with an outwardly projecting nozzle bar 18. This nozzle bar 18 has two flanks 27, 28, which project from the circumference and are connected at their ends through a web 21. In this web 21 are disposed linearly above one another several openings 22 extending over the entire length of the nozzle bar 18.

About the evaporator tube 17 is placed an insulating layer 26, comprised, for example, of a graphite felt or special ceramics, which is carried up to the front edges 19, 20 of the nozzle bar 18. About the insulating layer 26, which must withstand temperatures up to 1,700° C., is placed a tubular shielding 29, for example of metal, which, in turn, is encompassed by a double-walled tube, preferably of metal, whose walls 30 and 31 are connected with one another through webs 32, 33. Between these webs 32, 33 a cooling means, for example water, may flow, i.e. the webs 32, 33 form cooling means channels. The insulating layer 26, the shielding 29, and the double-walled tube have cutouts forming a recess at the site at which the nozzle bar 18 is located.

The nozzle bar 18 has very good thermal conductivity, which corresponds at least to the thermal conductivity of the evaporator tube 17.

Since the insulating layer 26 reaches to the front edges 19, 20 of the nozzle bar 18, the remaining evaporator tube is completely encompassed by the insulating layer, such that no heat can be radiated in the direction onto the substrate. Consequently, the heat radiated onto the substrate originates solely from the nozzle bar 18. However, this bar must be so hot that no condensation of the vapor takes place.

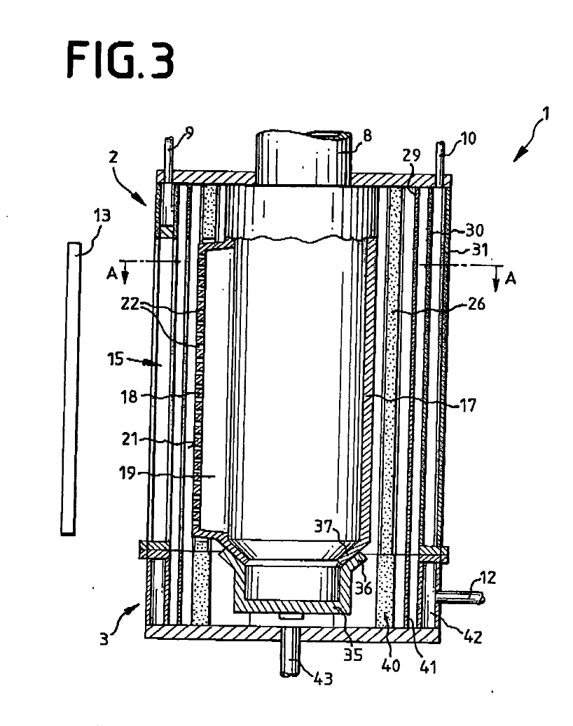

FIG. 3 shows a longitudinal section B-B through the vapor deposition device 1 according to FIG. 1. Herein the evaporator tube 17 can be seen seated on a crucible 35. The crucible 35 comprises at its upper end a flaring 36, while the evaporator tube 17 has a taper 37 at its lower end. This taper 37 rests on the flaring 36.

The flank 27 and the web 21 with the openings 22 of the nozzle bar 18 are shown to the left of the center of the evaporator tube 17.

By 40 is denoted a heating system for the crucible 35, which encompasses the crucible 35. This heating system 40 is encompassed by a shielding 41, which, in turn, is encompassed by a cooling system 42. A supply line for electrical energy is schematically denoted by 43.

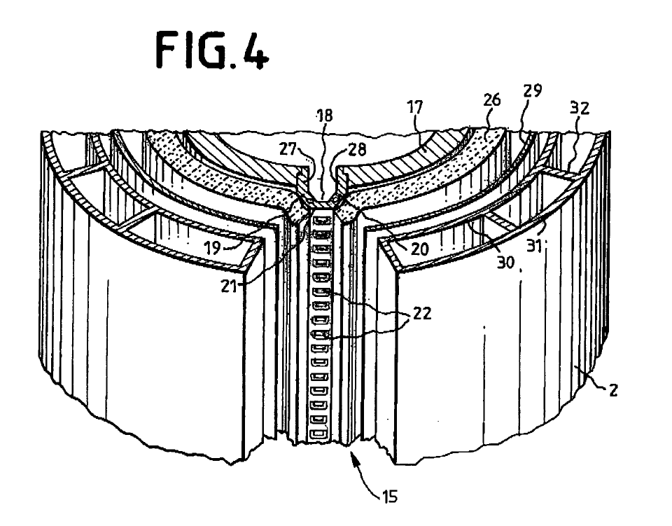

FIG. 4 shows an enlarged cut-out representation of FIG. 3. It is clearly evident that the insulating layer 26 is carried up to the front edges 19, 20 of the nozzle bar 18. It is additionally evident that the nozzle bar 18 can be comprised of a material different from that of the evaporator tube 17. Its flanks 27, 28 are adapted to the open ends of the evaporator tube 17.

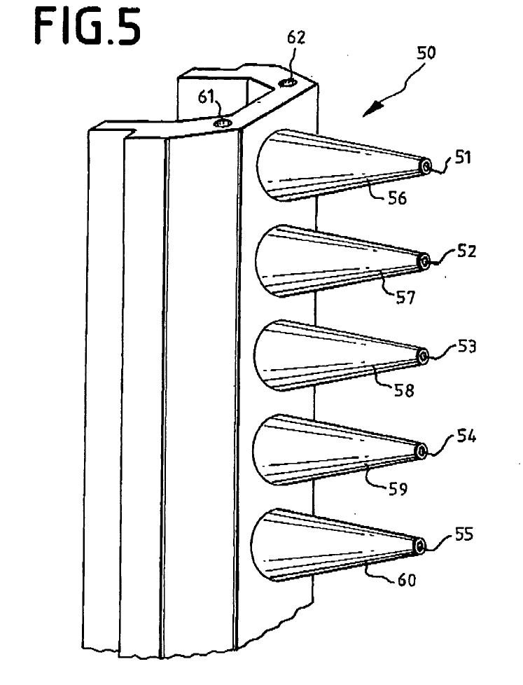

FIG. 5 shows a cut-out of another nozzle bar 50 in which, in comparison with the nozzle bar 18, the openings 51 to 55 are located forwardly. These openings 51 to 55 form the end of outwardly tapering cones 56 to 60, which are disposed on the nozzle bar 18. By 61, 62 are denoted the bores for the heating filaments. With such heating filaments the nozzle bar 18 can be heated independently of the evaporator tube 17.

If such a nozzle bar 50 with forwardly located nozzles is installed into an evaporator tube, it is possible to place insulating material over the cones 56 to 60.

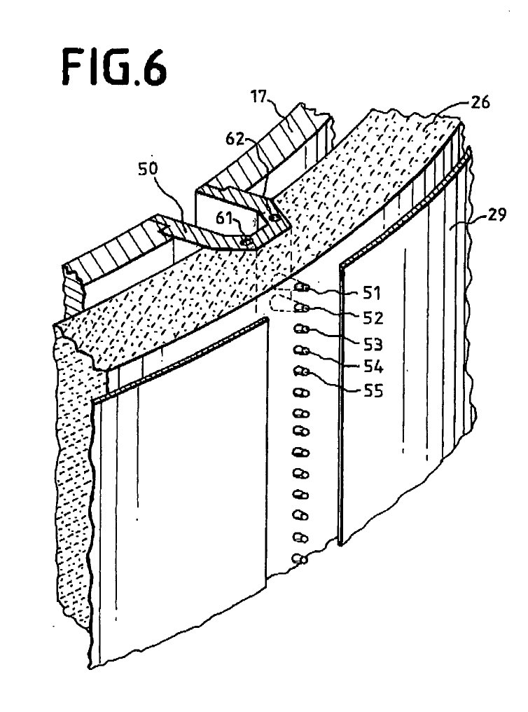

FIG. 6 shows the manner in which the cones 56 to 60 of the nozzle bar 50 are embedded in the insulating material. Consequently, the entire nozzle bar 50 is practically embedded in insulating material 26. Only the ends of the cones 56 to 60 are still capable of radiating heat.

The evaporator tube depicted in FIGS. 1 to 6 is always shown as a cylindrical tube. However, it is understood that it may also have the cross section of an n-gon and the sides may be equal or unequal. For example, it may have a rectangular, in particular square, cross section.

In all cases it makes possible a compact evaporator source, whose length—unlike in JP 2004-214185—does not need to correspond to the length of the evaporator bar.

1-13. (canceled)

14. A vapor deposition device for the vapor deposition of a substrate comprising:
an evaporator source, in which the surface of material to be vaporized extends substantially perpendicularly to the direction of the gravitational force of the earth; and
an evaporator chamber, located above the evaporator source and whose longitudinal axis extends parallel to the direction of the gravitational force of the earth, wherein the evaporator chamber comprises a nozzle bar provided with several linearly disposed outlet openings and the outlet openings in the nozzle bar extend perpendicularly to the direction of the gravitational force of the earth, wherein the region of the nozzle bar, in which are located the outlet openings, is located forwardly of the vaporizer chamber.

15. The vapor deposition device as claimed in claim 14, wherein the evaporator chamber is formed as a cylindrical tube.

16. The vapor deposition device as claimed in claim 14, wherein the evaporator chamber is formed as a rectangular tube.

17. The vapor deposition device as claimed in claim 14, wherein the evaporator chamber is encompassed by a thermal insulating layer which extends up to the nozzle bar, located fowardly.

18. The vapor deposition device as claimed in claim 14, wherein the nozzle bar is formed in the shape of a U, wherein the one ends of the side flanks of the nozzle bar are connected with the evaporator tube and the other ends with a web.

19. The vapor deposition device as claimed in claim 14, wherein the nozzle bar is provided with its own heating system.

20. The vapor deposition device as claimed in claim 19, wherein the heating system is a resistance heating system.

21. The vapor deposition device as claimed in claim 17, wherein the thermal insulating layer is encompassed by a shielding.

22. The vapor deposition device as claimed in claim 21, wherein the shielding is encompassed by a double-walled jacket which includes cooling means channels.

23. The vapor deposition device as claimed in claim 14, wherein the nozzle bar forwardly located has a thermal conductivity at least equal to that of the evaporator tube.

24. The vapor deposition device as claimed in claim 14, wherein the nozzle bar comprises several outwardly tapering cones, which are arranged linearly and at their ends have an opening.

25. The vapor deposition device as claimed in claim 24, wherein the cones are embedded in insulating material.

26. A vapor deposition device for the vapor deposition of a substrate with an evaporator source and an evaporator chamber disposed at least in the proximity of the evaporator chamber, wherein this evaporator chamber comprises a nozzle bar with several outlet openings wherein that region of the nozzle bar, in which the outlet openings are located, is located forwardly of the evaporator chamber and that the evaporator chamber over its circumference is provided with a thermal insulating layer, which extend up to the nozzle bar without covering the outlet openings.

27. A method comprising subjecting a substrate to vapor deposition with the vapor deposition device of claim 14.

28. A method comprising subjecting a substrate to vapor deposition with the vapor deposition device of claim 26.

29. The vapor deposition device as claimed in claim 26, wherein the evaporator chamber is formed as a cylindrical tube.

30. The vapor deposition device as claimed in claim 26, wherein the evaporator chamber is formed as a rectangular tube.

31. The vapor deposition device as claimed in claim 26, wherein the nozzle bar is formed in the shape of a U, wherein the one ends of the side flanks of the nozzle bar are connected with the evaporator tube and the other ends with a web.

32. The vapor deposition device as claimed in claim 26, wherein the nozzle bar comprises several outwardly tapering cones, which are arranged linearly and at their ends have an opening.

33. The vapor deposition device as claimed in claim 32, wherein the cones are embedded in insulating material.
